(19) United States
(12) Patent Application Publication
(10) Pub. No.: US 2026/0180510 A1
(43) Pub. Date: Jun. 25, 2026

(54) AMPLIFIER DEVICE HAVING BUFFER FUNCTION

(71) Applicant: REALTEK SEMICONDUCTOR CORPORATION, HSINCHU (TW)

(72) Inventor: SHIH-HSIUNG HUANG, HSINCHU (TW)

(21) Appl. No.: 19/423,235

(22) Filed: Dec. 17, 2025

(30) Foreign Application Priority Data
Dec. 23, 2024 (TW) 113150233

(51) Int. Cl. H03F 1/02; H03F 3/04

(52) U.S. Cl. CPC H03F 1/0205; H03F 3/04

(57) ABSTRACT

An amplifier device having buffer function includes an amplifier circuit and a buffer circuit. The amplifier circuit is configured to amplify a first input signal to generate a first amplified output signal and to amplify a second input signal to generate a second amplified output signal. The buffer circuit is configured to generate a first buffered output signal according to a third input signal and to generate a second buffered output signal according to a fourth input signal. The amplifier circuit and the buffer circuit are coupled in series and coupled between a first power supply node and a second power supply node, the first power supply node receives a first power supply voltage, and the second power supply node receives a second power supply voltage.

### BACKGROUND OF THE INVENTION

### 1. Field of the Invention

The present disclosure relates to an amplifier device, particularly an amplifier device that may use the same biasing current to generate a buffered output and an amplified output.

### 2. Description of Related Art

In some applications, both a buffered output and an amplified output may be generated simultaneously for subsequent circuits. For example, portions of a circuit in an analog front‑end circuit or in a serializer/deserializer (SerDes) circuit (which may include, for example and not limited to, a variable‑gain amplifier and a mixed‑signal circuit) may use the buffered output and the amplified output. Alternatively, in an analog‑to‑digital converter (which may be, for example and not limited to, a pipeline analog‑to‑digital converter), certain signal path will use the buffered output, and another signal path will use the amplified output. In the existing approaches, several sets of circuits, which operate parallel with each other, are generally employed to generate the buffered output and the amplified output, thereby causing higher power consumption.

### SUMMARY OF THE INVENTION

In some aspects, an object of the present disclosure is to, but not limited to, provide, an amplifier device that may use the same biasing current to generate a buffered output and an amplified output, so as to make an improvement to the prior art.

In some aspects, an amplifier device having buffer function includes an amplifier circuit and a buffer circuit. The amplifier circuit is configured to amplify a first input signal to generate a first amplified output signal and to amplify a second input signal to generate a second amplified output signal. The buffer circuit is configured to generate a first buffered output signal according to a third input signal and to generate a second buffered output signal according to a fourth input signal. The amplifier circuit and the buffer circuit are coupled in series and coupled between a first power supply node and a second power supply node, the first power supply node receives a first power supply voltage, and the second power supply node receives a second power supply voltage.

These and other objectives of the present disclosure will no doubt become obvious to those of ordinary skill in the art after reading the following detailed description of the preferred embodiments that are illustrated in the various figures and drawings.

### BRIEF DESCRIPTION OF THE DRAWINGS

FIG. 1 illustrates a schematic diagram of an amplifier device having buffer function according to some embodiments of the present disclosure.

FIG. 2 illustrates a schematic diagram of an amplifier device having buffer function according to some embodiments of the present disclosure.

FIG. 3 illustrates a schematic diagram of the amplifier circuit in FIG. 1 or FIG. 2 according to some embodiments of the present disclosure.

FIG. 4 illustrates a schematic diagram of the buffer circuit in FIG. 1 according to some embodiments of the present disclosure.

FIG. 5 illustrates a schematic diagram of the buffer circuit in FIG. 1 according to some embodiments of the present disclosure.

FIG. 6 illustrates a schematic diagram of the buffer circuit in FIG. 4 according to some embodiments of the present disclosure.

FIG. 7 illustrates a schematic diagram of the buffer circuit in FIG. 4 according to some embodiments of the present disclosure.

FIG. 8 illustrates a schematic diagram of the buffer circuit in FIG. 4 according to some embodiments of the present disclosure.

### DETAILED DESCRIPTION OF THE PREFERRED EMBODIMENTS

The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

In this document, the term “coupled” may also be termed as “electrically coupled,” and the term “connected” may be termed as “electrically connected.” “Coupled” and “connected” may mean “directly coupled” and “directly connected” respectively, or “indirectly coupled” and “indirectly connected” respectively. “Coupled” and “connected” may also be used to indicate that two or more elements cooperate or interact with each other. In this document, the term “circuit” may indicate an object, which is formed with one or more transistors and/or one or more active/passive elements according to a specific arrangement, for processing signals.

As used herein, the term "and/or" includes any and all combinations of one or more of the associated listed items. Although the terms “first,” “second,” etc., may be used herein to describe various elements, these elements should not be limited by these terms. These terms are used to distinguish one element from another. For example, a first element could be termed a second element, and, similarly, a second element could be termed a first element, without departing from the scope of the embodiments. For ease of understanding, similar/identical elements in various figures are designated with the same reference number.

FIG. 1 illustrates a schematic diagram of an amplifier device 100 having buffer function according to some embodiments of the present disclosure. The amplifier device 100 includes an amplifier circuit 110 and a buffer circuit 120. The amplifier circuit 110 amplifies an input signal VIN1 to generate an amplified output signal VO1, and amplifies an input signal VIN2 to generate an amplified output signal VO2. The buffer circuit 120 generates a buffered output signal BO1 according to an input signal VIN3 and generates a buffered output signal BO2 according to an input signal VIN4. The amplifier circuit 110 and the buffer circuit 120 are coupled in series and coupled between a power supply node PN1 and a power supply node PN2, in which the power supply node PN1 receives a power supply voltage V1 and the power supply node PN2 receives a power supply voltage V2 lower than the power supply voltage V1.

With the above arrangements, the amplifier circuit 110 and the buffer circuit 120 may be biased by the same current flowing between the power supply node PN1 and the power supply node PN2. As a result, it is able to utilize a single biasing current to generate amplified signal outputs (that is, the amplified output signal VO1 and the amplified output signal VO2) and buffered output s (that is, the buffered output signal BO1 and the buffered output signal BO2) . In this example, the amplifier circuit 110 is coupled between the power supply node PN1 and the buffer circuit 120, and the buffer circuit 120 is coupled between the amplifier circuit 110 and the power supply node PN2, but the present disclosure is not limited thereto.

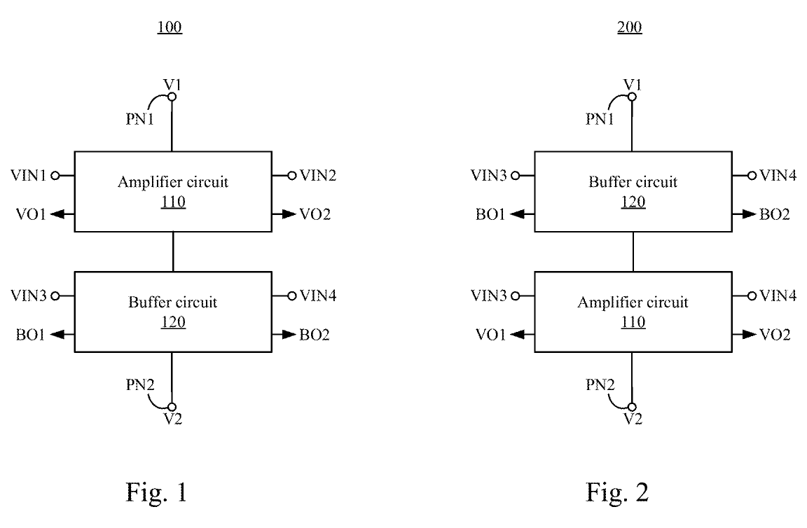

FIG. 2 illustrates a schematic diagram of an amplifier device 200 having buffer function according to some embodiments of the present disclosure. Compared with FIG. 1, in this example, the buffer circuit 120 is coupled between the power supply node PN1 and the amplifier circuit 110, and the amplifier circuit 110 is coupled between the buffer circuit 120 and the power supply node PN2. That is, different from FIG. 1, the buffer circuit 120 is coupled to the power supply node PN1 to receive a power supply voltage V1, and the amplifier circuit 110 is coupled to the power supply node PN2 to receive a power supply voltage V2. In other words, in different embodiments, a connection relationship between the amplifier circuit 110 and the buffer circuit 120 between the power supply node PN1 and the power supply node PN2 may be swapped with each other.

In some embodiments, the input signal VIN1 and the input signal VIN3 may be the same signal (that is, the input signal VIN1 may be the same as the input signal VIN3), and the input signal VIN2 and the input signal VIN4 may be the same signal (that is, the input signal VIN2 may be the same as the input signal VIN4). In some embodiments, the input signal VIN1 and the input signal VIN2 may be differential signals, and the input signal VIN3 and the input signal VIN4 may be differential signals. In some embodiments, one of the input signal VIN1 and the input signal VIN3 may be generated based on another of the input signal VIN1 and the input signal VIN3. Similarly, in some embodiments, one of the input signal VIN2 and the input signal VIN4 may be generated based on another of the input signal VIN2 and the input signal VIN4. For example, the amplifier device 100 (or the amplifier device 200) may further include a first level shifter circuit (not shown) and a second level shifter circuit (not shown). The first level shifter circuit may adjust a direct‑current (DC) level of the input signal VIN1 to generate the input signal VIN3, and the second level shifter circuit may adjust a DC level of the input signal VIN2 to generate the input signal VIN4. Alternatively, the first level shifter circuit may adjust the DC level of the input signal VIN3 to generate the input signal VIN1, and the second level shifter circuit may adjust the DC level of the input signal VIN4 to generate the input signal VIN2. In other words, in some embodiments, the input signal VIN1 and the input signal VIN3 may be signals having different DC levels, and the input signal VIN2 and the input signal VIN4 may be signals having different DC levels.

The above related settings for the input signal VIN1, the input signal VIN2, the input signal VIN3, and the input signal VIN4 are given for illustrative purposes, and the present disclosure is not limited thereto. In different embodiments, the input signal VIN1, the input signal VIN2, the input signal VIN3, and the input signal VIN4 may be configured according to actual application requirements.

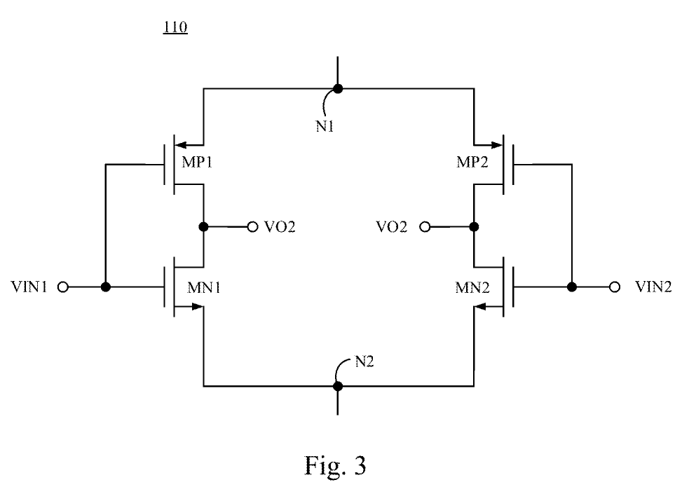

FIG. 3 illustrates a schematic diagram of the amplifier circuit 110 in FIG. 1 or FIG. 2 according to some embodiments of the present disclosure. The amplifier circuit 110 includes a P‑type transistor MP1, a P‑type transistor MP2, an N‑type transistor MN1, and an N‑type transistor MN2. The P‑type transistor MP1 and the N‑type transistor MN1 are coupled in series and configured to generate an amplified output signal VO1 according to an input signal VIN1. Similarly, the P‑type transistor MP2 and the N‑type transistor MN2 are coupled in series and configured to generate an amplified output signal VO2 according to an input signal VIN2.

In greater detail, a first terminal (e.g., a source) of the P‑type transistor MP1 and a first terminal of the P‑type transistor MP2 are coupled to a node N1, a second terminal (e.g., a drain) of the P‑type transistor MP1 is coupled to a first terminal (e.g., a drain) of the N‑type transistor MN1 and configured to generate an amplified output signal VO1, a control terminal (e.g., a gate) of the P‑type transistor MP1 and a control terminal (e.g., a gate) of the N‑type transistor MN1 receive an input signal VIN1, and a second terminal (e.g., a source) of the N‑type transistor MN1 and a second terminal of the N‑type transistor MN2 are coupled to a node N2. A second terminal of the P‑type transistor MP2 is coupled to a first terminal of the N‑type transistor MN2 and configured to generate an amplified output signal VO2, and a control terminal of the P‑type transistor MP2 and a control terminal of the N‑type transistor MN2 receive an input signal VIN2. With the above arrangements, the P‑type transistor MP1 and the N‑type transistor MN1 may operate as an amplifier that may amplify the input signal VIN1 to generate the amplified output signal VO1, and the P‑type transistor MP2 and the N‑type transistor MN2 may operate as another amplifier that may amplify the input signal VIN2 to generate the amplified output signal VO2.

In the embodiment of FIG. 1, the node N1 is coupled to the power supply node PN1, and the node N2 is coupled to the buffer circuit 120. In the embodiment of FIG. 2, the node N1 is coupled to the buffer circuit 120, and the node N2 is coupled to the power supply node PN2. As described above, in some embodiments, the input signal VIN1 and the input signal VIN2 may be differential signals. Under this condition, an alternating‑current (AC) component of the node N1 may be substantially zero and an AC signal component of the node N2 may be substantially zero. For example, the input signal VIN1 may be expressed as VCM+ΔV, the input signal VIN2 may be expressed as VCM−ΔV, where VCM is a DC common‑mode level of the input signal VIN1 and the input signal VIN2, and ΔV is an AC signal component. Through coupling between the P‑type transistor MP1 and the P‑type transistor MP2, the AC signal components ΔV may cancel each other at the node N1, thereby making the AC signal component at the node N1 substantially zero. Similarly, the AC signal components ΔV may also cancel each other at the node N2 through coupling between the N‑type transistor MN1 and the N‑type transistor MN2. Therefore, with the above arrangements, two nodes N1 and N2 having an AC signal component equal to substantially zero may be formed. Thus, the amplifier circuit 110 may be coupled to the buffer circuit 120 through the node N1 and/or the node N2, so that the same current between the power supply node PN1 and the power supply node PN2 may be used for biasing.

The arrangement of the amplifier circuit 110 shown in FIG. 3 is given for illustrative purposes, but the present disclosure is not limited thereto. Various types of the amplifier circuit 110 are all within the contemplated scope of the present disclosure.

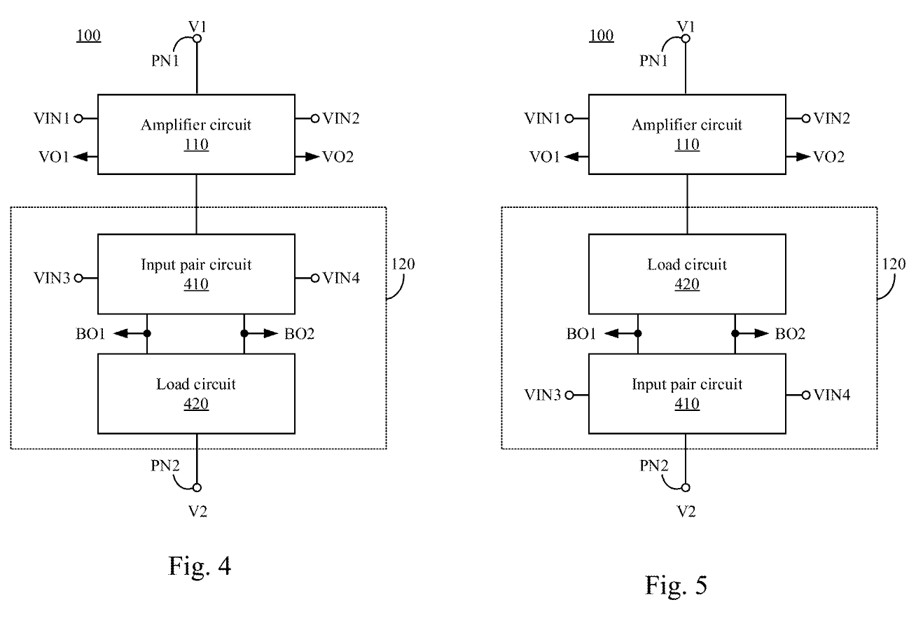

FIG. 4 illustrates a schematic diagram of the buffer circuit 120 in FIG. 1 according to some embodiments of the present disclosure. The buffer circuit 120 includes an input pair circuit 410 and a load circuit 420. The input pair circuit 410 is configured to receive the input signal VIN3 and the input signal VIN4. The load circuit 420 is coupled to the input pair circuit 410 and may provide an active (or passive) load to generate the buffered output signal BO1 and the buffered output signal BO2. In this example, the load circuit 420 may be coupled to the amplifier circuit 110 through the input pair circuit 410.

FIG. 5 illustrates a schematic diagram of the buffer circuit 120 in FIG. 1 according to some embodiments of the present disclosure. Different from FIG. 4, in this example, the input pair circuit 410 may be coupled to the amplifier circuit 110 through the load circuit 420. The coupling relationships and operations of related components may be understood with reference to the description of FIG. 4 and will not be repeated here. In other words, in different embodiments, a connection relationship between the input pair circuit 410 and the load circuit 420 may be exchanged with each other. With this analogy, it is understood that the arrangement shown in FIG. 4 and FIG. 5 may also be applied to the buffer circuit 120 of FIG. 2.

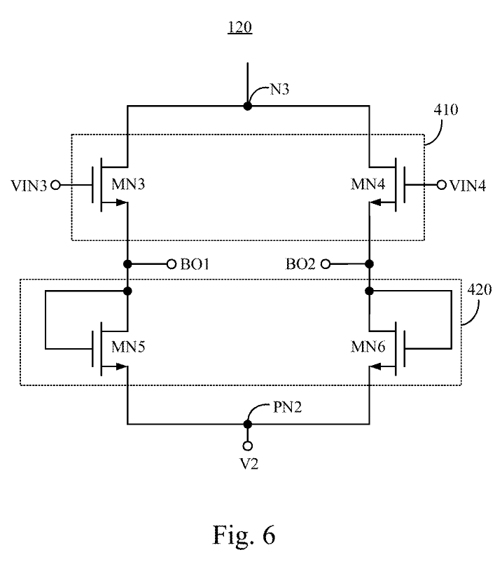

FIG. 6 illustrates a schematic diagram of the buffer circuit 120 in FIG. 4 according to some embodiments of the present disclosure. In this example, the input pair circuit 410 includes an N‑type transistor MN3 and an N‑type transistor MN4, and the load circuit 420 includes an N‑type transistor MN5 and an N‑type transistor MN6. A first terminal of the N‑type transistor MN3 and a first terminal of the N‑type transistor MN4 are coupled to a node N3, a second terminal of the N‑type transistor MN3 is coupled to a first terminal and a control terminal of the N‑type transistor MN5 and generates the buffered output signal BO1, and a control terminal of the N‑type transistor MN3 receives an input signal VIN3. A second terminal of the N‑type transistor MN4 is coupled to a first terminal and a control terminal of the N‑type transistor MN6 and generates the buffered output signal BO2, and a control terminal of the N‑type transistor MN4 receives an input signal VIN4. A second terminal of the N‑type transistor MN5 and a second terminal of the N‑type transistor MN6 are coupled to the power supply node PN2. In this example, each of the N‑type transistor MN5 and the N‑type transistor MN6 is arranged as a diode‑connected transistor to operate as an active load of the N‑type transistor MN3 and the N‑type transistor MN4. In other words, the N‑type transistor MN3 and the N‑type transistor MN5 operate as a source follower to generate a buffered output signal BO1 according to the input signal VIN3. Similarly, the N‑type transistor MN4 and the N‑type transistor MN6 operate as another source follower to generate the buffered output signal BO2 according to the input signal VIN4.

As described above, the input signal VIN3 and the input signal VIN4 may be differential signals. Under this condition, similar to the node N1 or the node N2 described above, through coupling between the N‑type transistor MN3 and the N‑type transistor MN4, AC signal components of the input signal VIN3 and the input signal VIN4 may cancel each other at the node N3. Therefore, the AC signal component at the node N3 may be substantially zero. Thus, the buffer circuit 120 may be coupled to the amplifier circuit 110 through the node N3, so that the same current between the power supply node PN1 and the power supply node PN2 may be used for biasing.

It should be understood that the arrangement shown in FIG. 6 may also be applied to the embodiment of FIG. 5. In other words, in other embodiments, a connection relationship between the input pair circuit 410 and the load circuit 420 in FIG. 6 may be exchanged with each other (as shown in FIG. 5), but the N‑type transistors MN3, MN4, MN5, and the N‑type transistor MN6 in FIG. 6 may be replaced by P‑type transistors (depending on actual bias requirements).

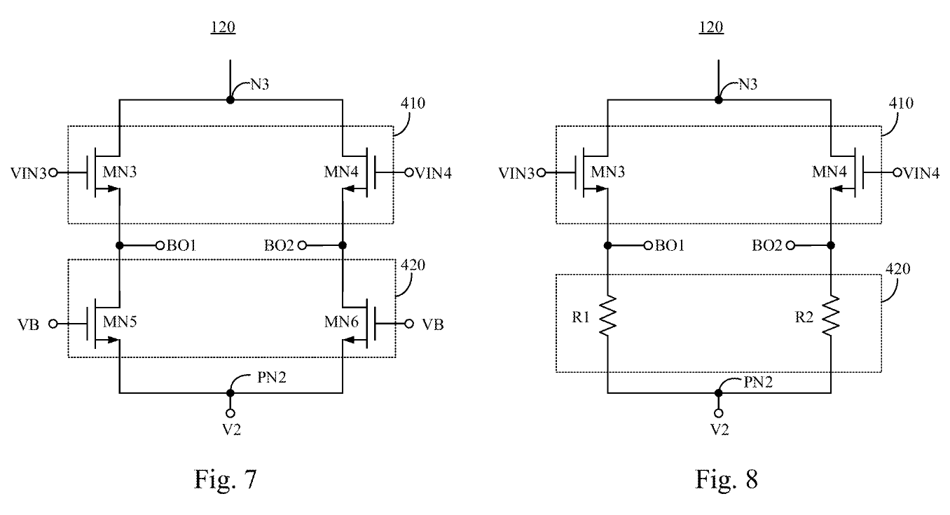

FIG. 7 illustrates a schematic diagram of the buffer circuit 120 in FIG. 4 according to some embodiments of the present disclosure. Different from FIG. 6, in this example, the N‑type transistor MN5 and the N‑type transistor MN6 receive a bias voltage VB and operate as a current‑source‑type load. That is, the N‑type transistor MN5 and the N‑type transistor MN6 may operate as an active load according to the bias voltage VB, rather than being arranged as diode‑connected transistors.

FIG. 8 illustrates a schematic diagram of the buffer circuit 120 in FIG. 4 according to some embodiments of the present disclosure. Different from FIG. 6 or FIG. 7, in this example, the load circuit 420 includes a resistor R1 and a resistor R2. The resistor R1 is coupled between a second terminal of the N‑type transistor MN3 and the power supply node PN2, and the resistor R2 is coupled between a second terminal of the N‑type transistor MN4 and the power supply node PN2. Different from the above embodiments, in this example, the load circuit 420 employs the resistor R1 and the resistor R2 to provide a passive load.

As described above, the analog buffer device provided in some embodiments of the present disclosure may employ the same current to bias source follower circuits, so as to generate buffered output signals while reusing the bias current.

Various functional components or blocks have been described herein. As will be appreciated by persons skilled in the art, in some embodiments, the functional blocks will preferably be implemented through circuits (either dedicated circuits, or general purpose circuits, which operate under the control of one or more processors and coded instructions), which will typically include transistors or other circuit elements that are configured in such a way as to control the operation of the circuitry in accordance with the functions and operations described herein. As will be further appreciated, the specific structure or interconnections of the circuit elements will typically be determined by a compiler, such as a register transfer language (RTL) compiler. RTL compilers operate upon scripts that closely resemble assembly language code, to compile the script into a form that is used for the layout or fabrication of the ultimate circuitry. Indeed, RTL is well known for its role and use in the facilitation of the design process of electronic and digital systems.

The aforementioned descriptions represent merely some embodiments of the present disclosure, without any intention to limit the scope of the present disclosure thereto. Various equivalent changes, alterations, or modifications according to the claims of present disclosure are all consequently viewed as being embraced by the scope of the present disclosure.

What is claimed is:

1. An amplifier device having buffer function, comprising:
an amplifier circuit configured to amplify a first input signal to generate a first amplified output signal and to amplify a second input signal to generate a second amplified output signal; and
a buffer circuit configured to generate a first buffered output signal according to a third input signal and to generate a second buffered output signal according to a fourth input signal,
wherein the amplifier circuit and the buffer circuit are coupled in series and coupled between a first power supply node and a second power supply node, the first power supply node receives a first power supply voltage, and the second power supply node receives a second power supply voltage.

2. The amplifier device having buffer function of claim 1, wherein the amplifier circuit is coupled between the first power supply node and the buffer circuit, and the buffer circuit is coupled between the amplifier circuit and the second power supply node.

3. The amplifier device having buffer function of claim 1, wherein the buffer circuit is coupled between the first power supply node and the amplifier circuit, and the amplifier circuit is coupled between the buffer circuit and the second power supply node.

4. The amplifier device having buffer function of claim 1, wherein the buffer circuit comprises:
an input pair circuit configured to receive the third input signal and the fourth input signal; and
a load circuit coupled to the input pair circuit to generate the first buffered output signal and the second buffered output signal,
wherein the load circuit is coupled to the amplifier circuit through the input pair circuit.

5. The amplifier device having buffer function of claim 4, wherein the input pair circuit comprises a plurality of transistors coupled at a first node, and an AC signal component at the first node is substantially zero.

6. The amplifier device having buffer function of claim 5, wherein the buffer circuit is coupled to the amplifier circuit through the first node.

7. The amplifier device having buffer function of claim 1, wherein the buffer circuit comprises:
an input pair circuit configured to receive the third input signal and the fourth input signal; and
a load circuit coupled to the input pair circuit to generate the first buffered output signal and the second buffered output signal,
wherein the input pair circuit is coupled to the amplifier circuit through the load circuit.

8. The amplifier device having buffer function of claim 1, wherein the first input signal is the same as the third input signal.

9. The amplifier device having buffer function of claim 1, wherein one of the first input signal and the third input signal is generated based on another of the first input signal and the third input signal.

10. The amplifier device having buffer function of claim 1, wherein the amplifier circuit comprises:
a first N‑type transistor;
a first P‑type transistor, wherein the first P-type transistor and the first N-type transistor are coupled in series and configured to generate the first amplified output signal according to the first input signal;
a second N‑type transistor; and
a second P‑type transistor, wherein the second P-type transistor and the second N-type transistor are coupled in series and configured to generate the second amplified output signal according to the second input signal.

11. The amplifier device having buffer function of claim 10, wherein the first N‑type transistor and the second N‑type transistor are coupled at a first node, and an AC signal component at the first node is substantially zero.

12. The amplifier device having buffer function of claim 11, wherein the amplifier circuit is coupled to the buffer circuit through the first node.

13. The amplifier device having buffer function of claim 10, wherein the first P‑type transistor and the second P‑type transistor are coupled at a second node, and an AC signal component at the second node is substantially zero.

14. The amplifier device having buffer function of claim 13, wherein the amplifier circuit is coupled to the buffer circuit through the second node.

15. The amplifier device having buffer function of claim 1, wherein the second input signal is the same as the fourth input signal.

16. The amplifier device having buffer function of claim 1, wherein one of the second input signal and the fourth input signal is generated based on another of the second input signal and the fourth input signal.

17. The amplifier device having buffer function of claim 1, wherein the first input signal and the third input signal have different DC levels.
